(19) United States
(12) Patent Application Publication
(10) Pub. No.: US 2023/0326939 A1
(43) Pub. Date: Oct. 12, 2023

(54) HIGH-DQE DIRECT DETECTION IMAGE SENSOR FOR ELECTRONS WITH 40 - 120 KEV ENERGY

(71) Applicant: DIRECT ELECTRON, LP, San Diego, CA (US)

(72) Inventors: Benjamin BAMMES, San Diego, CA (US); Robert BILHORN, San Diego, CA (US)

(73) Assignee: DIRECT ELECTRON, LP, San Diego, CA (US)

(21) Appl. No.: 18/042,505

(22) PCT Filed: Jul. 26, 2021
(86) PCT No.: PCT/US2021/043156

§ 371 Date: Feb. 22, 2023

Related U.S. Application Data
(60) Provisional application No. 63/073,719, filed on Sep. 2, 2020.

(51) Int. Cl. H01L 27/146; G01T 1/24

(52) U.S. Cl. CPC H01L 27/14612; G01T 1/244; H01L 27/14659; H01L 27/14683

(57) ABSTRACT

A detector is provided for forming images by detecting electrons in an electron microscope at energies in the range of 3 keV to 300 keV, more specifically in the range of 40 keV to 120 keV with very high spatial resolution and sensitivity. The detector is formed by bonding a handling wafer to the front side of a planarized monolithic active pixel sensor (MAPS), partially or completely removing the substrate layer on the back side and selectively removing the handling material from the front side to leave a periphery of handling material in the non-image forming area. The detector may be mounted in an electron microscope for back side illumination. The detector provides high resolution images at low-energies due to back side illumination and at higher energies due to a decreased epitaxial layer thickness and the absence of any backscattering substrate material.

### CROSS-REFERENCE TO RELATED APPLICATION

This application claims benefit to U.S. Provisional Application No. 63/073,719, filed Sep. 2, 2020, which is incorporated herein by reference in its entirety.

### FIELD

The present disclosure relates to a direct detection sensor and camera system for high detective quantum efficiency (high-DQE) imaging of electrons with energy ranging from 3 keV to 300 keV, and more specifically electrons ranging from 40 keV to 120 keV.

### BACKGROUND

Devices currently used for forming images by detecting electrons in the electron microscope do not provide high spatial resolution and sensitivity in the energy range of 40 keV to 120 keV. Direct Detection Devices (DDD®) and other detectors that detect electrons without the use of intervening scintillators work well at energies above 120 keV. These systems achieve detective quantum efficiency (DQE), which is a measure of sensitivity and resolution, near theoretical limits by using electron counting. Alternatively, detectors using scintillators suffer from resolution-limiting blur and diffuse scattering of light, resulting in a limited DQE. However, because direct detectors perform poorly at low energies, detection of <120 keV electrons has so far relied on scintillator-based detectors.

Two types of detector technology are used for the direct detection of electrons in microscopy. The first enjoys wide adoption and is used almost exclusively in biological applications where specimens are held at cryogenic temperatures while imaging (cryo-EM). These are monolithic active pixel sensors (MAPS) produced using complementary metal oxide semiconductor (CMOS) image sensor manufacturing processes. A schematic cross-section of such a sensor is shown schematically in FIG. 1. These sensors are built on an approximately 1 mm thick silicon wafer 110 upon which is grown a lightly doped epitaxial p-type silicon layer (epi) 120 of 5 μm-30 μm thickness. The circuitry 130 is then built on or built within the epi layer 120 using CMOS image sensor manufacturing processes. An n-type photodiode 121 is formed in a depletion region 122 and topped by a p⁺⁺ pinned layer 123. The epitaxial material is p-type silicon. The substrate 110 is a p⁺ type silicon substrate. A floating diffusion region, FD, is an n-type region. The photodiode acts like a source and the floating diffusion acts like a drain of a MOS transistor. A metallization pattern forms a source contact to the p⁺⁺ region of the photodiode, a drain contact 132 to the floating diffusion region and a transfer gate 134 contact. Electrons interact with the silicon as they penetrate the device, producing signal charge that is collected and read out by read out circuitry 140. As shown in FIG. 2, each incident electron 212 produces many secondary electrons 216 in a cloud trail as they traverse and scatter through the detector. Interactions in the epi layer 220 are the ones of interest as they produce the charge that is collected. Some fraction of incident electrons can undergo scattering at large angles either within the epi layer or material under the epi layer—which is called backscattering—and as a result deposit secondary charge in locations far from their point of entry (as shown by backscattered electron 214, FIG. 2) thereby degrading image quality. To minimize this effect some fraction of the substrate wafer may be removed to reduce the amount of backscattering as shown in FIG. 2. In FIG. 2, the epi layer 220 has been manufactured to be approximately 10 μm thick and the substrate layer has been thinned from approximately 1 mm to approximately 20 μm in thickness. The incident electron energy is 300 keV.

MAPS detectors work very well at electron energies at 200 keV and above, achieving near-ideal DQE. High-energy primary electrons generate a relatively small and localized cloud of secondary electrons as they pass through the detector's epi layer. The limited size of the secondary electron cloud ensures that the signal from each primary electron does not spread over many pixels. Additionally, the high-energy primary, electron is unlikely to scatter at high angles in subsequent material, so that backscattering is minimized, provided that the detector is sufficiently thin.

However, the performance of MAPS detectors falls off dramatically at lower electron energies because of increased electron scattering at lower energy as shown in FIG. 3, where the primary electron energy is 100 keV. This low energy causes three problems. First, low-energy primary electrons 312 tend to generate many secondary electrons in the epi layer 320, causing pixels to saturate with fewer primary electrons. Second, low-energy primary electrons and their resulting secondary electron cloud trail 316 tend to scatter across many pixels, causing the point-spread function of the detector to expand and reducing the resolution of the detector, as shown by comparing the size of the interaction volume in FIG. 3 to that shown in FIG. 2. Third, low-energy primary electrons tend to scatter at high angles upon interaction with any material under the epi layer, resulting in a greater number of backscattered electrons 314. These backscattered electrons 314 cause detection of secondary events far from the original point of incidence of the primary electrons. Backscattering both reduces resolution, as measured by the modulation transfer function (MTF), and increases noise by adding extra false positives.

A second type of detector used for directly detecting electrons in the electron microscope is the hybrid pixel detector (HPD) shown in FIG. 4. The hybrid pixel detector provides for electron imaging in the electron energy range of interest, at high-DQE. These devices are a hybridization between an aluminum detector layer 430 that absorbs the primary electron to produce a cloud of secondary electrons and a readout circuitry layer 440 that reads out the number and locations of interactions. The two layers are electrically connected to each other through a process called bump bonding involving indium or similar metal “bumps” 442 that create connections between the detector layer 430 and readout pixels 446. A voltage 445 is applied between the aluminum detector layer 430 and the p-type silicon layer 444. As shown in FIG. 4, a p-type silicon layer 444 captures the electron/hole disturbances generated by the impinging primary electron beam 412 and an electric current is conveyed through the solder bump 442 to the read-out circuitry layer 440. Unlike modem MAPS detectors used in electron microscopy that allow primary electrons to pass completely through the sensitive volume, HPDs strive to stop the primary electron in a relatively thicker detector layer. Note the dimensions of the layers in these detectors are generally about 10 times larger than for MAPS detectors.

Hybrid pixel detectors work best at lower electron energies (i.e., 120 keV or less) where the incident electron can be stopped in the detector layer, but their performance deteriorates as the energy is increased because of the increasing volume of the secondary charge cloud and the possibility that primary electrons will completely penetrate the detecting layer before being stopped, thereby depositing less than their full energy. There have been some efforts recently to increase the performance of HPDs for high energy electrons (i.e., 200 keV or more) by using higher-Z materials (higher atomic number, e.g., germanium (Ge), gallium arsenide (GaAs), cadmium telluride (CdTe), and cadmium zinc telluride (CZT)) besides silicon for the detecting layer.

There are two significant limitations of HPDs, which limit their usefulness for imaging methods such as cryo-EM. First, it is difficult in these sensors to account for detection events that spread over multiple pixels. The use of large (i.e., >50 m wide) pixels reduces the likelihood that a primary electron will deposit energy over multiple pixels, but it remains possible, especially when the primary electron interacts with the sensor near the border between two pixels. Large pixels are also necessary in HPDs to accommodate the space required by the readout circuitry. Second, the use of large pixels in HPDs severely limits the overall size of the pixel array (total number of pixels). Large arrays of HPDs require tiling smaller devices and at some point, the arrays grow too large to be practical for electron microscopy. Current generation HPDs are limited to about 0.5 megapixels-1.0 megapixels, while MAPs detectors achieve sizes up to 67 megapixels.

MAPS sensors used at 200 keV and 300 keV have been tested at lower energies but DQE is not sufficiently high. The same is true for scintillator-coupled CCD and CMOS systems. HPDs have shown promise at the energy range of interest but because of their pixel size, arrays on the order of 100 mm on a side would be necessary to provide a 4 megapixel field-of-view, which is not practical both due to space constraints on electron microscopes and manufacturing cost.

Despite the lack of high-quality detectors, there is significant interest in operating electron microscopes within the range of 60 kV to 120 kV for studies in both the life and materials sciences.

Back side illumination of an electron microscope detector has been used without removal of the substrate. For example, a series of lens electrodes or a scintillator were used to decelerate the electrons before they reached the substrate. (See. e.g., U.S. Patent App. Pub. No. 2010/0123082A1).

For example, in materials science, the use of low energy electrons limits knock-on damage and allows for effective study of the structure of graphene. (See Bachmatiuk A, Zhao J, Gorantla S M, Martinez I G G, Wiedermann J, Lee C, Eckert J, Rummeli M H, “Low voltage transmission electron microscopy of graphene”, Small 11(5): 515-42 (2015).)

In life science, there is a growing push for effective low-cost 100 kV cryo-EM instruments. A peer-reviewed paper by Nobel laureate Richard Henderson was recently published to demonstrate the high-resolution potential of such a system. However, this paper concluded that, “Currently, the lack of a suitable high-speed, high-efficiency detector with a large number of pixels (>4×10⁶) is the primary limitation both to the ultimate achievable resolution and to the practical use of a 100 keV transmission electron microscope for cryoEM.” (See Naydenova K, McMullan G, Peet M J, Lee Y, Edwards P C, Chen S, Leahy E, Scotcher S, Henderson R. & Russo C J, “CryoEM at 100 keV: a demonstration and prospects”, IUCrJ 6(6): 1086-1098 (2019), and Hand E, “We need a people's cryo-EM. Scientists hope to bring revolutionary microscope to the masses”, Science (2020), available at www.sciencemag.org.)

Accordingly, it is an object of the present disclosure to provide a device, system and method for a direct detection sensor and camera system for high-DQE imaging of electrons with energy ranging from 3 keV to 300 keV, and more specifically electrons ranging from 40 keV to 120 keV to fill the need for a high-speed, high efficiency detector with a large number of pixels and high image resolution.

### SUMMARY

The present disclosure describes a direct detection sensor and camera system for high-DQE imaging of electrons with energy ranging from 3 keV to 300 keV, and more specifically for electrons ranging from 40 keV to 120 keV. A camera is provided that can image electrons in the electron microscope at high resolution and with a large field of view at electron beam energies that are scientifically interesting but that were difficult to use previously. The system also represents an approach that is practical to manufacture at volume and modest cost.

According to an embodiment, a method of forming a direct detector for imaging ionizing radiation in a transmission electron microscope is described, comprising forming a monolithic active pixel sensor in a CMOS image sensor process, wherein the sensor includes an epitaxial silicon layer disposed on a silicon substrate and a CMOS layer disposed on the epitaxial silicon layer, bonding a handling wafer material to the front side of the CMOS layer, removing the silicon substrate to reveal a back side of the epitaxial silicon layer, selectively removing a first section of the handling wafer material from a sensing region of the CMOS layer and leaving a second section of the handling wafer material around the periphery of the sensing region, wherein the direct detector is configured to be mounted in the transmission electron microscope by contacting only the second section, and wherein the direct detector is further configured such that the ionizing radiation enters from only the back side of the epitaxial silicon layer.

According to another embodiment, direct detector for imaging ionizing radiation is described, the detector comprising a monolithic active pixel sensor including an epitaxial silicon layer disposed on a silicon substrate and a CMOS layer disposed on the epitaxial silicon layer, a handling wafer bonded to a front side of the CMOS layer, wherein the substrate has been removed down to a back side of the epitaxial silicon layer and wherein a first section of the handling wafer has been selectively removed from a region corresponding to the pixel sensor leaving a second section of the handling wafer at the periphery of the sensor.

According to an embodiment, a method of ionizing radiation in a transmission electron microscope, comprising providing a monolithic active pixel sensor which includes an epitaxial layer disposed between a CMOS layer and a silicon substrate, wherein providing the monolithic active detector includes: planarizing a front side of the CMOS layer, bonding a handling wafer to a front side of the CMOS layer, removing the silicon substrate to reveal a back side of the epitaxial silicon layer, selectively removing a first section of the handling wafer from a sensing region of the CMOS layer and leaving a second section of the handling wafer around the periphery of the sensing region, mounting the detector in the transmission electron microscope, orienting the detector so that the ionizing radiation enters the detector from the back side of the epitaxial silicon layer, and reading out signals representing the ionizing radiation.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross section of a monolithic active pixel sensor;

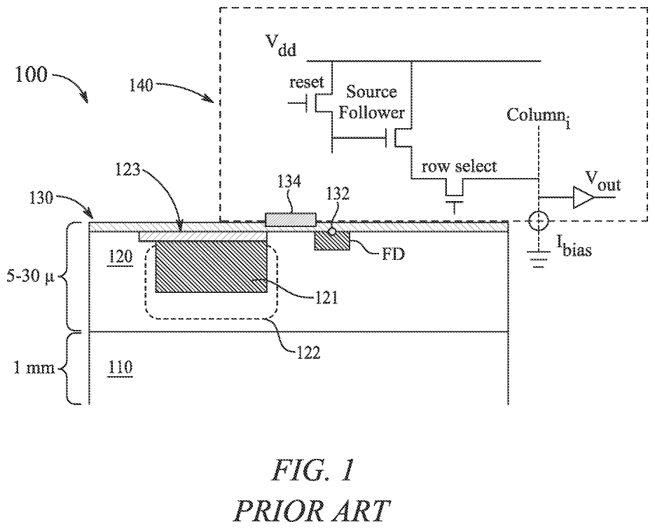

FIG. 2 is a thinned MAPS sensor showing the charge cloud produced by an incident primary electron;

FIG. 3 illustrates the primary electron energy level effect on the secondary electron cloud size at 100 keV;

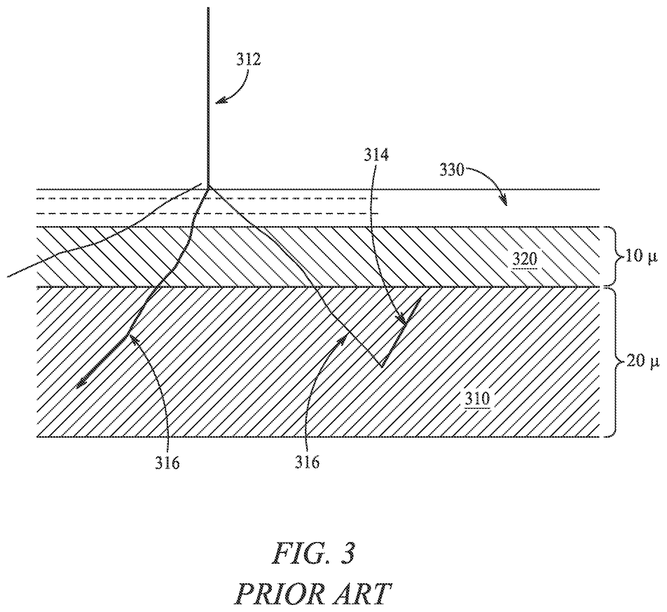

FIG. 4 illustrates a schematic cross section of a hybrid pixel detector;

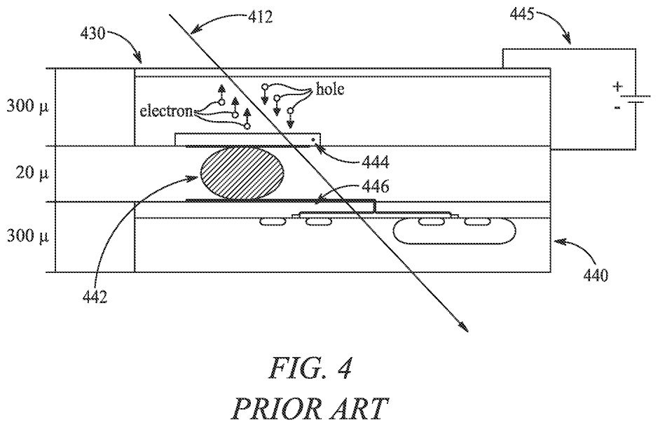

FIG. 5 illustrates an electron detector fabricated in the epi layer of a silicon wafer;

FIG. 6 illustrates a silicon handling wafer bonded over the electron detector:

FIG. 7 illustrates the electron detector following removal of the original substrate silicon leaving the back surface of the epi layer exposed and the handling wafer providing mechanical support:

FIG. 8 illustrates the electron detector following selective removal of handling wafer material;

FIG. 9 illustrates the electron detector back side orientation relative to a primary electron beam;

FIGS. 10A-10B illustrate an image of a beamstop with the selected area (SA) aperture inserted on a TEM operating at 100 kV in electron counting mode: “A” for the entire image, and “B” for a zoomed in view of the end of the beamstop;

FIG. 11A is a graph illustrating the MTF and DQE of the prototype sensor for 100 kV cryo-EM.

FIG. 11B is a graph comparing the DQE of the prototype sensor at 100 kV to a conventional sensor at 300 kV:

FIG. 12A illustrates a resolution assessment at 100 kV of the prototype sensor showing the Thon rings at 3.5 Angstroms:

FIG. 12B illustrates the Fourier transform of an image of a line grating replica grid collected under low-dose cryo-EM conditions in electron counting mode on the prototype sensor:

FIG. 13A illustrates a cryo-EM micrograph of mouse heavy chain apoferritin collected at 100 kV by the prototype sensor showing a cropped region from the final image;

FIG. 13B illustrates the Fourier transform of the image of FIG. 13A; and

FIG. 13C illustrates rotationally-averaged power spectrum showing Thon rings out to about 4 Å resolution.

### DETAILED DESCRIPTION

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). Reference throughout this document to “one embodiment”, “certain embodiments”, “an embodiment”, “an implementation”, “an example” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

The sensitive layer in the detector of the present disclosure remains near the top surface (because it is a back side illumination (BSI) MAPS device), therefore the sensor performs well for lower-energy electrons (i.e., 1 keV-60 keV), and because the sensor is sufficiently thin, it also performs well for higher-energy electrons (i.e., 120 keV-300 keV). Therefore, for the first time, a MAPS detector sensitive to the entire range of electron energies typically used in electron microscopy is described.

Back-thinning and back side illumination have been used for visible and ultraviolet photon detection, and thinned and back side illuminated MAPS sensors for detection of electrons below about 25 keV in energy have been tested. These sensors do not require removal of handling wafer material since the primary beam electrons do not penetrate beyond the epi layer thickness. However, these sensors do not work well at higher electron energies because of backscattering from the handling wafer material.

High-DQE is important in an electron detector to for use in electron microscopy. Current scintillator-coupled CCD or CMOS sensors and current direct detection MAPS sensors do not provide sufficient DQE.

Other requirements for detecting electrons in an electron microscope are for a large field-of-view with at least 4 megapixels, which is a physical size compatible with current microscope designs. Another concern is to minimize conversion costs and total cost of ownership (TCO). Although HPD sensors offer high-DQE, they cannot practically satisfy these other requirements because of the large pixels necessary in these devices. Large devices have several disadvantages, the two most important being that they do not easily fit in microscopes as they are currently designed, and they are more expensive. Two factors drive cost: first, fewer devices fit on a silicon wafer, and second, the yield per device drops as area goes up. The hybridization step also adds cost.

The present disclosure describes a monolithic active pixel sensor fabricated in epi silicon from which all or essentially all of the substrate silicon has been removed and which is oriented in the electron beam such that primary beam electrons are incident on the epi-vacuum interface.

The device fabrication is described below.

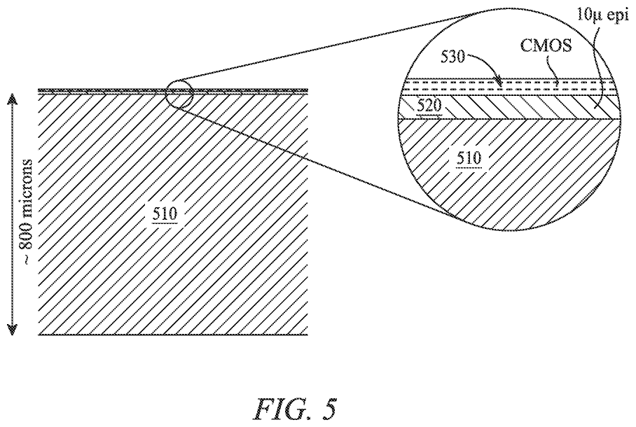

FIG. 5 shows fabrication of the monolithic active pixel sensor on a standard epi wafer as would typically be used in a CMOS image sensor process. A CMOS circuitry layer 530, 10 μm epitaxial layer 520 and substrate layer 510 are shown in the inset for clarity.

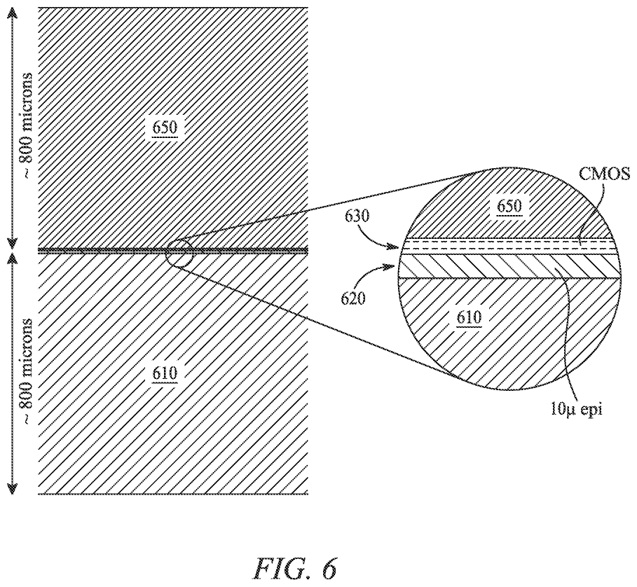

Following device fabrication, the top CMOS surface is planarized and then subsequently bonded to a secondary handling wafer 650 as shown in FIG. 6. A bond such as an oxide-oxide bond may be used. The CMOS layer 630, 10 μm epitaxial layer 620 and substrate layer 610 remain in place, as shown in the inset.

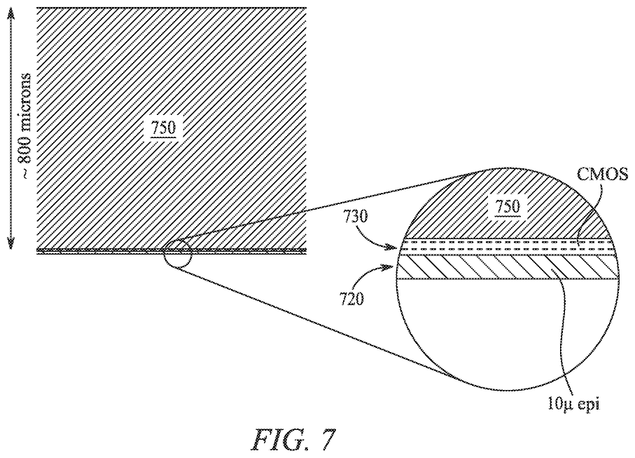

Once the handle wafer is in place, the substrate silicon is either partially or completely removed down to the epi-substrate junction or thereabouts using a process such as grinding followed by chemical-mechanical polish and/or chemical etching, resulting in the structure shown in FIG. 7, for example. The inset shows that the substrate layer has been removed, leaving the handling layer 750, the CMOS layer 730 and the 10 μm epitaxial layer 720. In some cases, a thin passivation layer may be added to the surface after removal of the substrate silicon.

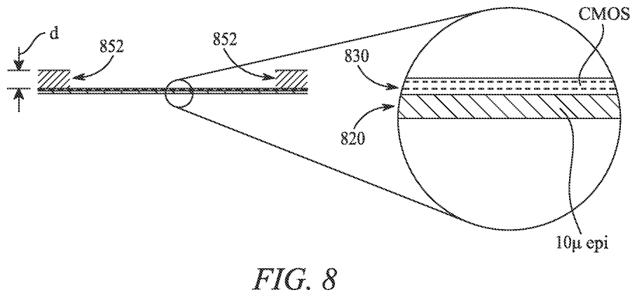

FIG. 8 shows the next step, in which the handling wafer is selectively removed from the area adjacent to the array of pixels leaving material 852 at the device periphery for strength. The thickness of material 852 is shown as d, which may be any thickness in the range of 1 microns to 800 microns. A process such as grinding followed by selective chemical etch may be used. The handle wafer may be completely removed from behind the pixel array, as shown in the inset showing the CMOS layer 830 and the 10 μm epitaxial layer 820, or some material may be left behind to provide additional rigidity. A tradeoff between mechanical strength and the degree of electron backscattering is made.

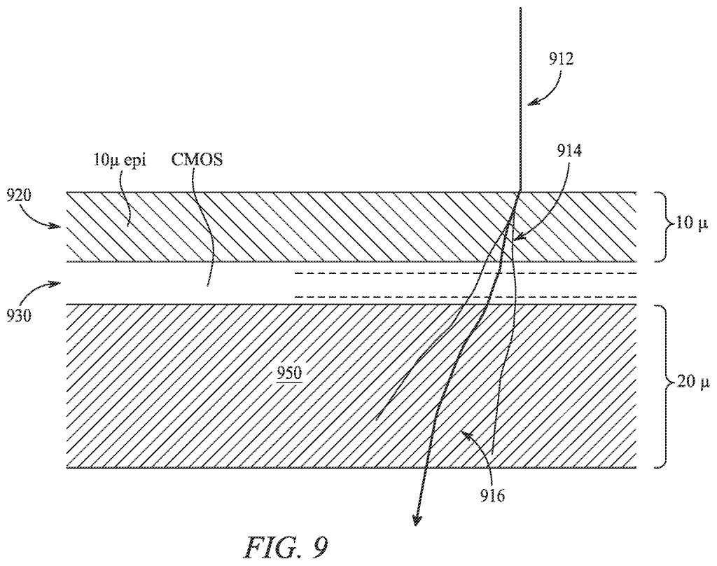

The device is mounted by attaching the mounting structure to the remaining handle wafer material along the periphery and then installed in a camera system so that primary beam electrons 912 enter the device from the side with the exposed epi layer 920 as shown in FIG. 9. The secondary electrons generated in the epi layer 920 form a tight grouping as they enter the CMOS circuitry layer 930. Backscattered electrons 916 in the 0-˜20 μm thick handling wafer 950 pass out of the device without being picked up by a photodiode.

The present disclosure uses a MAPS detector with back side illumination (BSI) once the substrate is removed combined with handling wafer removal from behind the active area to significantly reduce backscattering. This is the first known implementation of handling wafer removal behind a BSI MAPS device for the detection of electrons.

Conventional MAPS detectors for electron microscopy use front side illumination (FSI) with some of the substrate material removed to reduce backscattering. These conventional detectors are on the order of 30 μm thick. The BSI MAPS detector of the present disclosure provides for high resolution low-energy (<120 keV) electron imaging with a decreased thickness of about 10 μm to about 30 μm.

HPDs have also been proposed for detection of 40 keV-120 keV electrons. In these detectors, electrons enter the detection layer which is designed to be thick enough to absorb them. Photogenerated electron-hole pairs are separated by an applied electric field and the resulting current pulses are detected by an adjacent bump-bonded readout CMOS circuit. This is distinct from the architecture of MAPS detectors, which are monolithic, and generally require incident electrons to pass through the sensor without being completed absorbed.

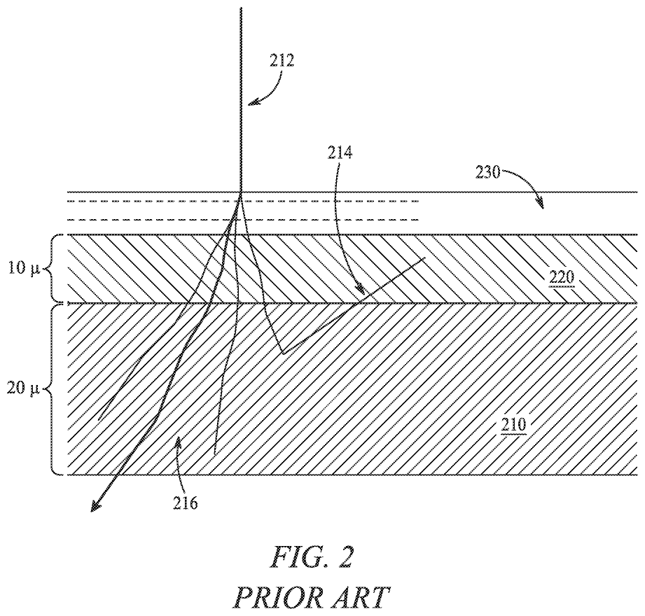

Referring again to FIG. 2 and FIG. 9, microscope electrons (212, 912) can enter the device from either the front side through CMOS layer 230 or the back side 920. The electrons interact with the silicon in the epitaxial silicon area 920 and generate conduction band electrons. Unlike photons, the microscope electrons carry much more energy and generate many conduction band electrons for each incident electron. The number of conduction band electrons generated depends on many factors including the incident energy of the system (e.g., microscope electrons).

FSI of MAPS detectors results in too much electron scattering and backscattering to yield high-DQE once primary beam energy drops below ˜200 keV. BSI and handling wafer removal are used to form the detector of the present disclosure which achieves high-DQE. Mechanical integrity is maintained by using a selective handling wafer removal technique that leaves material in the non-image forming area of the device. The device is mounted and cooled through this more robust peripheral area. The detector of the present disclosure has a high pixel density resulting in a practical way to achieve a large field-of-view for imaging at 40 keV-120 keV with high-DQE and has manufacturing costs similar to MAPS detectors currently used at higher primary beam energies.

Additionally, because the sensitive layer in the detector of the present disclosure remains near the top surface (because it is a BSI MAPS device), the sensor performs well for lower-energy electrons (i.e., 1 keV-60 keV), and because the sensor is sufficiently thin, it also performs well for higher-energy electrons (i.e., 60 keV-300 keV). Therefore, for the first time, a MAPS detector sensitive to the entire range of electron energies typically used in electron microscopy is described.

Finally, compared to HPDs, the small pixels of the detector of the present disclosure enable large pixel arrays within the space constraints of an electron microscope and minimize manufacturing costs, as multiple devices can be formed on a single silicon wafer.

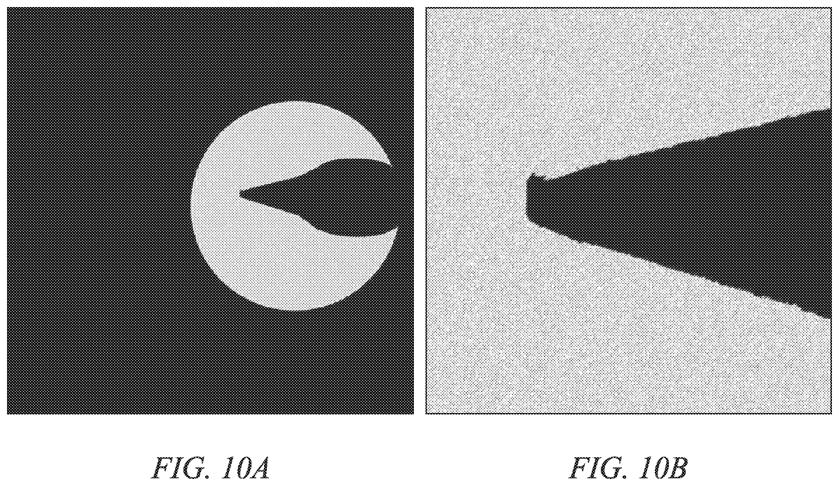

Two of the most significant problems with conventional direct detection sensors at 100 kV have been (1) poor resolution due to increased scattering of 100 kV primary electrons within the sensitive layer of the sensor, and (2) high background noise due to backscattering of 100 keV primary electrons. A 100 kV camera was installed on a Thermo Fisher Talos TEM equipped with a field-emission gun and aligned for 100 kV operation to test the detector. FIG. 10A shows an image of a selected area (SA) aperture of a beamstop detected by the detector of the present disclosure installed on the Thermo Fisher Talos TEM operating at 100 kV. This image has sharp edges (no noticeable blurring at the edges of the beamstop) and only 0.05% backscattering (based on the relative number of counts under the beamstop, which could only be present due to backscattering). FIG. 10B is a zoomed-in view of the end of the beamstop.

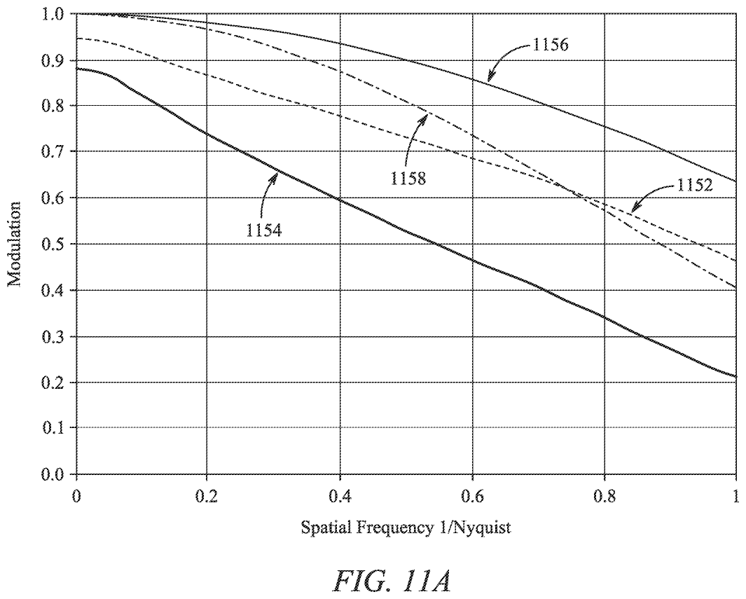

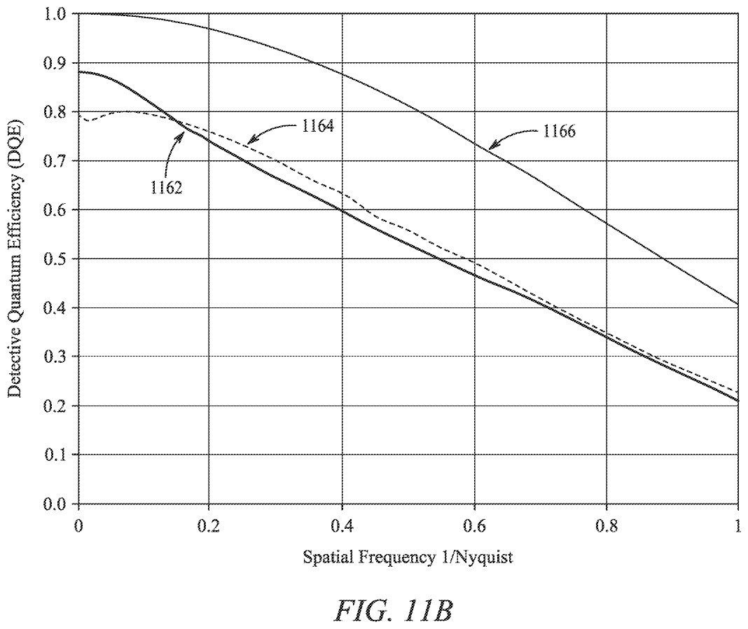

In order to generate a quantitative assessment, the MTF 1152 and the DQE 1154 of the prototype detector were calculated (FIG. 11A). The theoretical maximum MTF 1156 and theoretical maximum DQE 1158 are also plotted to compare the close response of the detector to the theoretical curves.

The MTF of a detector is a measurement of its ability to transfer contrast at a particular resolution from the object to the image, that is, the MTF determines how much contrast in the original object is maintained by the detector. In practice, the MTF is determined acquiring one or more images of straight (“knife”) edges on the detector, calculating the line-spread function (that is, the amount of blurring at the edge in the image) and converting the calculated real space line-spread function to frequency-space using a Fourier transform. The MTF is graphed as normalized modulation versus the spatial frequency at the inverse Nyquist limit. By definition, the value of the MTF at zero spatial frequency is unity but in the presence of long range scattering within the detector this can fall rapidly with increasing spatial frequency.

The MTF was calculated using eight images of a beamstop inserted, then collected in electron counting mode with a total detected exposure of 52.3 electrons per pixel spread over 5017 raw frames (resulting in an exposure rate per frame of 0.01 electrons per pixel per frame). Each image was processed independently (See. e.g., Ruskin, Yu, & Grigorieff, J Struct Biol 184: 385-393 (2013). “FindDQE v. 1.06”) and then the resulting MTF curves were averaged to generate the final MTF curve.

The DQE is defined as the ratio of the square of the output signal to noise ratio (S/N)ₒᵤₜ to the square of the input signal-to-noise ratio (S/N)ᵢₙ, and provides a measure of the quality with which incident electrons are recorded. A perfect detector has a DQE of unity at zero spatial frequency (DQI(0)) and to achieve this all incident electrons must be detected with equal weight. The DQE of real detectors is always smaller than unity reflecting the fact that in practice incident electrons are recorded with different weights. (DQE(0)) was calculated in several steps.

First, a histogram was plotted of the total integrated intensity of each detected event from raw integrating-mode frames collected of an empty specimen area. A total of 3,664,451 events were analyzed from a 256×256 region of interest in the middle of sensor. The histogram was fit to a Landau distribution using a curve fit function. (See, e.g., Landau, J Phys USSR 8: 201 (1944): scipy.optimize.curve_fit function, SciPy.org, Release 1.5.2, Jul. 23, 2020, available at docs.scipy.org). The fraction of incident electron missed by the detector was estimated using the integrated area under the fit Landau curve to be less than the counting threshold of the detector. This implied that 2.69% of incident electrons were missed by the detector, as this fraction of electrons deposited too little energy in the sensitive layer of the sensor and thus were below the noise level of the sensor. Therefore, the fit Landau curve implies that 97.3% of incident 100 keV electrons were detected by the sensor.

Second, the total number of detected events under a beamstop was compared to an illuminated area of the sensor. To reduce diffuse scattering on peripheral TEM and camera equipment, this data was collected with the SA aperture of the TEM inserted such that the illuminated area was smaller than the sensor. A 256×256 region under the beamstop had 1,981 detected events, whereas a 256×256 region in the illuminated area in the same data had 3,664,451 detected events. The ratio of these values implies that 0.054% of 100 keV primary electrons are backscattered within the camera, generating a false second detection.

The detected exposure rate on the sensor was therefore adjusted by dividing by 97.3% and multiplying by [100%-0.054%] to account for missed and backscattered electrons, respectively. The final calibrated exposure rate was 53.7 electrons per pixel per frame.

Finally, the DQE(0) was calculated using a noise binning method. (See. e.g., McMullan, Chen, Henderson, & Faruqi, Ultramicroscopy 109: 1126-1143 (2009)).

The final DQE curve was calculated by multiplying DQE(0) by MTF squared. Note that the noise power spectrum (NPS) has no impact, since it is unity for all spatial frequencies for electron counting MAPS detectors in the absence of coincidence loss. (See, e.g., Li, Zheng, Egami, Agard, & Cheng, J Struct Biol 184: 251-260 (2013)).

FIG. 11B shows that the performance of the prototype sensor for a 100 kV (line 1162) cryo-EM closely matches the performance of a conventional detector (Gatan K2-Summit) at 300 kV, with respect to the maximum DQE (line 1166) The DQE of the conventional detector at 300 kV (line 1164) was taken from McMullan, Faruqi, Clare, & Henderson, Ultramicroscopy 147: 156-163 (2014). This result clearly demonstrates the high performance of the prototype sensor at 100 kV.

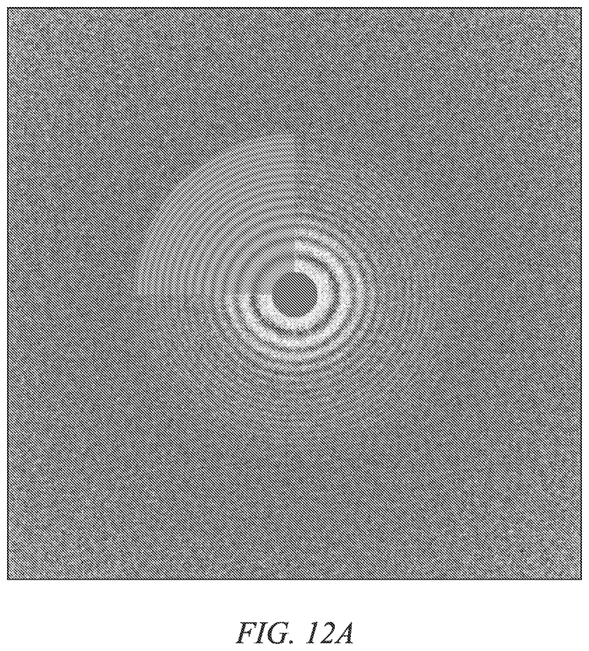

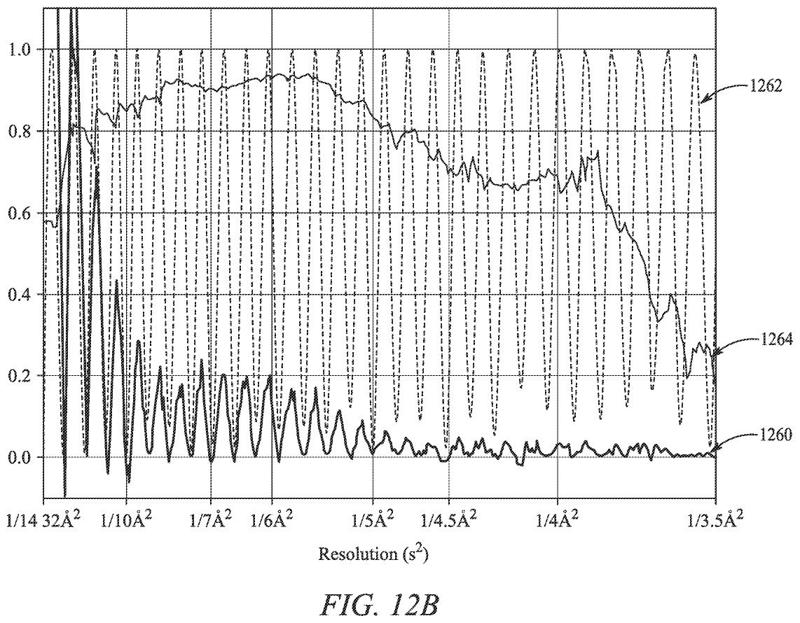

The contrast transfer function (CTF) is a mathematical description of the imaging process in the TEM expressed in Fourier space. Images of carbon film under low-dose cryo-EM conditions at 100 kV using the prototype sensor show Thon rings at up to about 3.5 Ångströms resolution are shown in FIG. 12A. The Fourier transform of the detected power spectra 1260 is compared to the CTF model 1262, and the quality of the fit 1264 is shown in FIG. 12B.

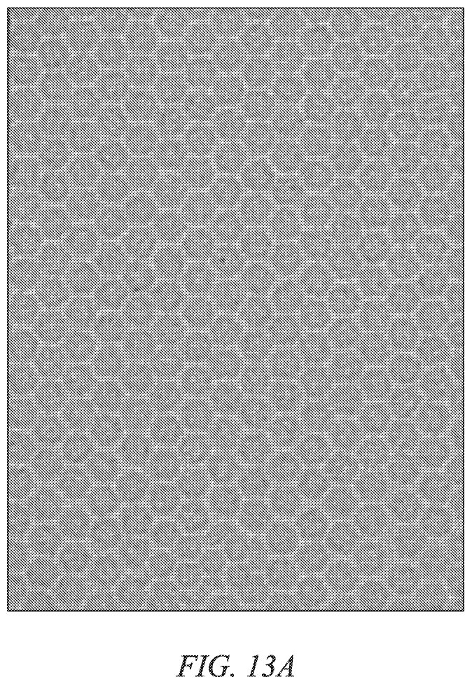

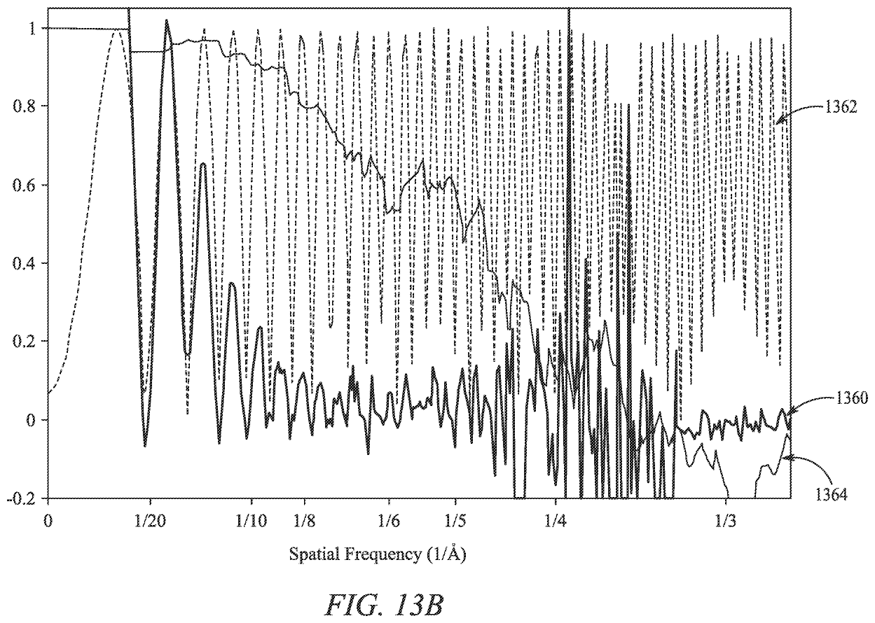

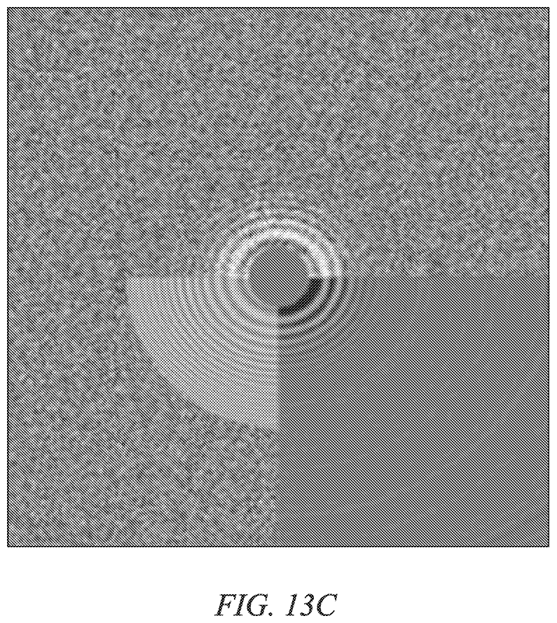

FIG. 13A shows that images of frozen-hydrated apoferritin (a standard cryo-EM specimen) exhibit high contrast and high resolution, as expected from the DQE curves. The nominal magnification of the microscope was 73,000 times, yielding sampling of 1.37 Å/pixel. The total exposure was about 40 e−/Å2. FIG. 13B shows the Fourier transform of the detected power spectra 1360 as compared to the CTF model 1362. The quality of the fit 1364 is shown. FIG. 13C illustrates the rotationally averaged power spectrum showing Thon rings out to about 4 resolution.

Embodiments of the present disclosure may also be as set forth in the following parentheticals.
(1) A method of forming a direct detector for imaging ionizing radiation in a transmission electron microscope is described, comprising forming a monolithic active pixel sensor in a CMOS image sensor process, wherein the sensor includes an epitaxial silicon layer disposed on a silicon substrate and a CMOS layer applied to the epitaxial silicon layer, bonding a handling wafer material to the front side of the CMOS layer, removing the silicon substrate to reveal a back side of the epitaxial silicon layer, selectively removing a first section of the handling wafer material from a sensing region of the CMOS layer and leaving a second section of the handling wafer material around the periphery of the sensing region, wherein the direct detector is configured to be mounted in the transmission electron microscope by contacting only the second section, and wherein the direct detector is further configured such that the ionizing radiation enters from only the back side of the epitaxial silicon layer.
(2) The method of (1), further comprising removing a first portion of the silicon substrate by a grinding process; and removing a remaining portion of the silicon substrate by chemical etching.
(3) The method of (1), further comprising: removing the first section of the handling wafer by selective chemical etching.
(4) The method of (1), further comprising: forming a photodiode in the epitaxial silicon layer; and forming a floating diffusion region in the epitaxial silicon layer.
(5) The method of any one of (1) to (4), further comprising: forming a metallization pattern on the CMOS layer which includes a photodiode contact, a floating diffusion contact and a gate contact; and connecting the floating diffusion contact to a read-out circuit.
(6) The method of any one of (1) to (5), further comprising: planarizing the front side of the CMOS layer before bonding the handling wafer.
(7) The method of any one of (1) to (6), further comprising: bonding the handling wafer material to the front side of the CMOS layer by an oxide to oxide bond.
(8) The method of any one of (1) to (7), further comprising: disposing the epitaxial layer to a thickness of 4 μm to 20 μm.
(9) A direct detector for imaging ionizing radiation, the detector comprising a monolithic active pixel sensor including an epitaxial silicon layer disposed on a silicon substrate and a CMOS layer disposed on the epitaxial silicon layer, a handling wafer bonded to a front side of the CMOS layer, wherein the substrate has been removed down to a back side of the epitaxial silicon layer and wherein a first section of the handling wafer has been selectively removed from a region corresponding to the pixel sensor leaving a second section of the handling wafer at the periphery of the sensor.
(10) The direct detector of (9), wherein the epitaxial layer is approximately 4 μm to 20 μm in thickness.
(11) The direct detector of either (9) or (10), wherein the monolithic active pixel sensor further includes: a depletion region in the epitaxial silicon layer, a photodiode in the depletion region, a pinned layer on the photodiode, and a floating diffusion region in the epitaxial silicon layer.
(12) The direct detector of any one of (9) to (11), wherein the epitaxial layer is a p-type silicon layer, wherein the photodiode is an n-type photodiode embedded in a depletion region: wherein the pinned layer is p⁺⁺ type silicon, and wherein the floating diffusion region is an n-type silicon material.
(13) The direct detector of any one of (9) to (12), wherein the CMOS layer includes: a metallization pattern on the front side, including a photodiode contact, a floating diffusion region contact and a gate contact, and a read-out circuit connected to the floating diffusion region.
(14) The direct detector of any one of (9) to (13), wherein the direct detector is configured to be mounted in a transmission electron microscope with orientation such that ionizing radiation enters the detector from the back side of the epitaxial silicon layer.
(15) A method of detecting ionizing radiation in a transmission electron microscope, comprising providing a monolithic active pixel sensor which includes an epitaxial layer disposed between a CMOS layer and a silicon substrate, wherein providing the monolithic active detector includes: planarizing a front side of the CMOS layer, bonding a handling wafer to a front side of the CMOS layer, removing the silicon substrate to reveal a back side of the epitaxial silicon layer, selectively removing a first section of the handling wafer from a sensing region of the CMOS layer and leaving a second section of the handling wafer around the periphery of the sensing region, mounting the detector in the transmission electron microscope, orienting the detector so that the ionizing radiation enters the detector from the back side of the epitaxial silicon layer, and reading out signals representing the ionizing radiation.
(16) The method of (15), wherein the ionizing radiation is electrons having an energy of 40 keV to 120 keV.
(17) The method of (15), wherein the ionizing radiation is electrons having an energy of 0 keV to 100 keV.
(18) The method of (15), wherein the ionizing radiation is electrons having an energy of 0 keV to 300 keV.
(19) The method of (15), wherein the ionizing radiation is electrons having an energy of 0 keV to 30 keV.
(20) The method of (15), further comprising: wherein the ionizing radiation is electrons having an energy of 100 keV.

The foregoing discussion discloses and describes exemplary embodiments of the present invention. As will be understood by those skilled in the art, the present invention may be embodied in other specific forms without departing from the spirit or essential characteristics thereof. Accordingly, the disclosure of the present invention is intended to be illustrative, but not limiting of the scope of the invention, as well as other claims. The disclosure, including any readily discernible variants of the teachings herein, defines, in part, the scope of the foregoing claim terminology such that no inventive subject matter is dedicated to the public.

1. A method of forming a direct detector for imaging ionizing radiation in a transmission electron microscope, comprising:
forming a monolithic active pixel sensor in a CMOS image sensor process, wherein the sensor includes an epitaxial silicon layer disposed on a silicon substrate and a CMOS layer disposed on the epitaxial silicon layer;
bonding a handling wafer material to a front side of the CMOS layer;
removing the silicon substrate to reveal a back side of the epitaxial silicon layer; and
selectively removing a first section of the handling wafer material from a sensing region of the CMOS layer and leaving a second section of the handling wafer material around a periphery of the sensing region,
wherein the direct detector is configured to be mounted in the transmission electron microscope by contacting only the second section, and
wherein the direct detector is further configured such that the ionizing radiation enters from only the back side of the epitaxial silicon layer.

2. The method of claim 1, further comprising:
removing a first portion of the silicon substrate by a grinding process; and
removing a remaining portion of the silicon substrate by chemical etching.

3. The method of claim 1, further comprising:
removing the first section of the handling wafer by selective chemical etching.

4. The method of claim 1, further comprising:
forming a photodiode in the epitaxial silicon layer; and
forming a floating diffusion region in the epitaxial silicon layer.

5. The method of claim 4, further comprising:
forming a metallization pattern on the CMOS layer that includes a photodiode contact, a floating diffusion contact, and a gate contact; and
connecting the floating diffusion contact to a read-out circuit.

6. The method of claim 1, further comprising:
planarizing the front side of the CMOS layer before the bonding of the handling wafer.

7. The method of claim 1, wherein the bonding of the handling wafer material to the front side of the CMOS layer is by an oxide-to-oxide bond.

8. The method of claim 1, wherein the epitaxial layer is disposed to a thickness of 4 μm to 20 μm.

9. A direct detector for imaging ionizing radiation, the detector comprising:
a monolithic active pixel sensor including an epitaxial silicon layer disposed on a silicon substrate and a CMOS layer disposed on the epitaxial silicon layer; and
a handling wafer bonded to a front side of the CMOS layer,
wherein the silicon substrate has been removed down to a back side of the epitaxial silicon layer, and
wherein a first section of the handling wafer has been selectively removed from a region corresponding to the pixel sensor leaving a second section of the handling wafer at a periphery of the pixel sensor.

10. The direct detector of claim 9, wherein the epitaxial layer is approximately 4 μm to 20 μm in thickness.

11. The direct detector of claim 9, wherein the monolithic active pixel sensor further includes:
a depletion region in the epitaxial silicon layer,
a photodiode in the depletion region,
a pinned layer on the photodiode, and
a floating diffusion region in the epitaxial silicon layer.

12. The direct detector of claim 11,
wherein the epitaxial layer is a p-type silicon layer,
wherein the photodiode is an n-type photodiode embedded in a depletion region,
wherein the pinned layer is p⁺⁺-type silicon, and
wherein the floating diffusion region is an n-type silicon material.

13. The direct detector of claim 11, wherein the CMOS layer includes:
a metallization pattern on the front side of the CMOS layer, including a photodiode contact, a floating diffusion region contact, and a gate contact, and
a read-out circuit connected to the floating diffusion region contact.

14. The direct detector of claim 9, wherein the direct detector is configured to be mounted in a transmission electron microscope with an orientation such that ionizing radiation enters the detector from the back side of the epitaxial silicon layer.

15. A method of detecting ionizing radiation in a transmission electron microscope, comprising:
providing a monolithic active pixel sensor which includes an epitaxial layer disposed between a CMOS layer and a silicon substrate, the monolithic active detector further including a handling wafer bonded to a front side of the CMOS layer, wherein the silicon substrate has been removed to reveal a back side of the epitaxial silicon layer, and wherein a first section of the handling wafer has been selectively removed from a sensing region of the CMOS layer while leaving a second section of the handling wafer around a periphery of the sensing region;
mounting the detector in the transmission electron microscope;
orienting the detector so that the ionizing radiation enters the detector from the back side of the epitaxial silicon layer; and
reading out signals from the detector representing the ionizing radiation.

16. The method of claim 15, wherein the ionizing radiation is electrons having an energy of 40 keV to 120 keV.

17. The method of claim 15, wherein the ionizing radiation is electrons having an energy of 0 keV to 100 keV.

18. The method of claim 15, wherein the ionizing radiation is electrons having an energy of 0 keV to 300 keV.

19. The method of claim 15, wherein the ionizing radiation is electrons having an energy of 0 keV to 30 keV.

20. The method of claim 15, wherein the ionizing radiation is electrons having an energy of 100 keV.
